(19) United States
(12) Patent Application Publication
(10) Pub. No.: US 2007/0153949 A1
(43) Pub. Date: Jul. 5, 2007

(54) PLL apparatus with power saving mode and method for implementing the same

(75) Inventors: Shang-Ping Chen, Tai-Chung City (TW); Tse-Hsiang Hsu, Hsin-Chu City (TW)

Correspondence Address: MADSON & AUSTIN;GATEWAY TOWER WEST, SUITE 900, 15 WEST SOUTH TEMPLE, SALT LAKE CITY, UT, 84101, US

(73) Assignee: MediaTek Incorporation

(21) Appl. No.: 11/321,921

(22) Filed: Dec. 29, 2005

(51) Int. Cl. H03D 3/24

(52) U.S. Cl. 375/374; 375/376

(57) ABSTRACT

The invention relates to a PLL apparatus with power saving mode and a method for implementing the same, comprising: a phase detector, a control unit, a charge pump, a loop filter, and a voltage control oscillator. The phase detector generates two detection signals indicating a phase difference between a reference signal and a feedback signal. When the power saving signal is set at a specific logic level, the control unit modifies the two detection signals to be at respective preset levels which keeps the charge pump either charging or discharging an input node of the loop filter to increase/decrease the control voltage outputted by the loop filter. Driven by such a control voltage, the voltage control oscillator generates an oscillating signal at a frequency lower than a normal working frequency so as to achieve power saving objective.

### BACKGROUND OF INVENTION

The present invention relates to a PLL (Phase Lock Loop) apparatus and method, and particularly a PLL apparatus with power saving mode and the method for implementing the same.

As is well known in the art, a PLL (Phase Lock Loop) circuit typically comprises a phase comparing unit, a loop filter, a voltage control oscillator (VCO), and an optional frequency divider. The phase comparing unit typically includes a phase frequency detector (PFD) or phase detector (PD), and a charge pump. The phase (frequency) detector, which is well known for a person skilled in this art, receives a feedback signal and a reference signal and generates a first and second detection signals for indicating a phase difference between the feedback and reference signals.

FIGS. 6A and 6B depict two examples of the reference signal, the feedback signal and the corresponding first and second detection signals. In these examples, the phase (frequency) detector generates the first and second detection signals based on the rising edges of the reference and feedback signals. In the case shown in FIG. 6A where the rising edges of the reference signal leads the rising edges of the feedback signal, the first detection signal will be logic high at the time points of the rising edges of the reference signal and return to be logic low at the time points of the raising edges of the feedback signal. The second detection signal will be kept at logic low in this case. In another case shown in FIG. 6B where the rising edges of the reference signal lag behind the rising edges of the feedback signal, the second detection signal will be logic high at the time points of the rising edges of the feedback signal and return to be logic low at the time points of the raising edges of the reference signal. The first detection signal will be kept at logic low in this case.

As is well known in the art, one of the detection signals, e.g. the first detection signal, is used to instruct the charge pump to charge or stop charging an output node of the charge pump, and the other detection signal, e.g. the second detection signal, is used to instruct the charge pump to discharge or stop discharging the output node. Thereby, a phase difference signal is formed at the output node of the charge pump. The loop filter such as a typical low pass filter is utilized to suppress a high-frequency component of the phase difference signal and then generates a control voltage. Next, the VCO is driven by the control voltage to output an oscillating signal having a frequency corresponding to the control voltage. In general, the frequency of the oscillating signal could be designed to be either proportional or inversely proportional to the control voltage. The output frequency signal is then fed back to the phase comparing unit to serve as the feedback signal. In some cases, a frequency divider is additionally employed to divide the frequency of the oscillating signal to obtain a divided frequency signal, which is fed back to the phase comparing unit to serve as the feedback signal.

In most applications, a normal working frequency of the oscillating signal outputted by the VCO is very high. As is well known, a signal generated at a high frequency implies higher power consumption. Therefore, if the frequency of the oscillating signal can be decreased, the power consumption would thus be greatly reduced as a result. This leads a signification point for electrical device with limited power supply.

### SUMMARY OF INVENTION

It is a primary objective of the present invention to provide a PLL apparatus with power saving mode and method for implementing a power saving function.

To achieve the forgoing objective, one of the embodiments of the instant invention discloses a PLL apparatus with power saving mode comprising: a phase comparing unit, a loop filter, a voltage control oscillator, and a frequency divider. The phase comparing unit receives a reference signal, a feedback signal and a power saving signal, and correspondingly outputs a phase difference signal indicating a phase difference between the reference and feedback signals.

In a first embodiment, the phase comparing unit has a phase (frequency) detector (PD or PFD), a control unit and a charge pump. The phase (frequency) detector is used to detect a phase difference between the reference and feedback signals and operationally outputs two detection signals.

The control unit includes an inverter, a AND gate and an OR gate, and receives said two detection signals. When the power saving signal is set at a first logic level for a power saving mode, the control unit modifies the two detection signals into two modified detection signals, which are respectively fixed at present logic levels regardless of logic levels of the detection signals. Then, as soon as the power saving signal at a second logic level is set for a normal operation mode, the two modified detection signals outputted from the control unit are respectively set identical to the detection signals.

Based on the two modified detection signals being fixed at preset logic levels, the charge pump correspondingly keeps charging or discharging an input node of a loop filter for increasing or decreasing a control voltage at a certain saturation value to drive the voltage control oscillator to output an oscillating signal at a frequency lower than a normal working frequency of the oscillating signal, serving as the feedback signal to the phase frequency detector.

Besides, in one example of the present invention, a method for implementing power saving of a PLL apparatus is introduced, comprises the following steps of:

receiving a reference signal, a feedback signal and a power saving signal from a phase comparing unit of the PLL apparatus;

generating a first and second detection signals by a phase detector of the phase comparing unit, therefore, indicating a phase difference between the reference signal and feedback signal in response to the power saving signal;

when the power saving signal is at the first level, modifying the first detection signal at a preset logic level by way of performing an AND operation on the first detection signal and the inverted power saving signal, and modifying the second detection signal at a preset logic level by way of performing an OR operation on the second detection signal and the power saving signal;

outputting a phase difference signal from the phase comparing unit at an input node of a loop filter, based on the modified detection signals; and

keeping either charging or discharging the input node of the loop filter to increase/decrease a control voltage thereby driving a voltage control oscillator to output an oscillating signal at a frequency lower than a normal working frequency of the oscillating signal, thereby serving as the feedback signal, so as to achieve power saving objective of the PLL apparatus.

These and other objectives of the present invention will no doubt become obvious to those of ordinary skill in the art after reading the following detailed descriptions of the preferred embodiments that are illustrated in the various figures and drawings.

### BRIEF DESCRIPTION OF DRAWINGS

FIG. 1 illustrates a schematic diagram of a PLL apparatus with power saving mode according to a first preferred embodiment of the present invention, presenting a control unit behind a phase (frequency) detector;

FIG. 2 illustrates a schematic diagram of a PLL apparatus with power saving mode according to a second preferred embodiment of the present invention, differing from the structure of the control unit shown in FIG. 1;

FIG. 3 illustrates a schematic diagram of a PLL apparatus with power saving mode according to a third preferred embodiment of the present invention, presenting a gating unit prior to a phase frequency detector;

FIG. 4 illustrates a schematic diagram of a PLL apparatus with power saving mode according to a fourth preferred embodiment of the present invention, differing from the layout of the gating unit shown in FIG. 3;

FIG. 5 illustrates a flow chart of a method for implementing power saving of a PLL apparatus; and

FIGS. 6A and 6B show two timing charts each indicating a relative wave variance of the reference signal, the feedback signal and the corresponding first and second detection signals.

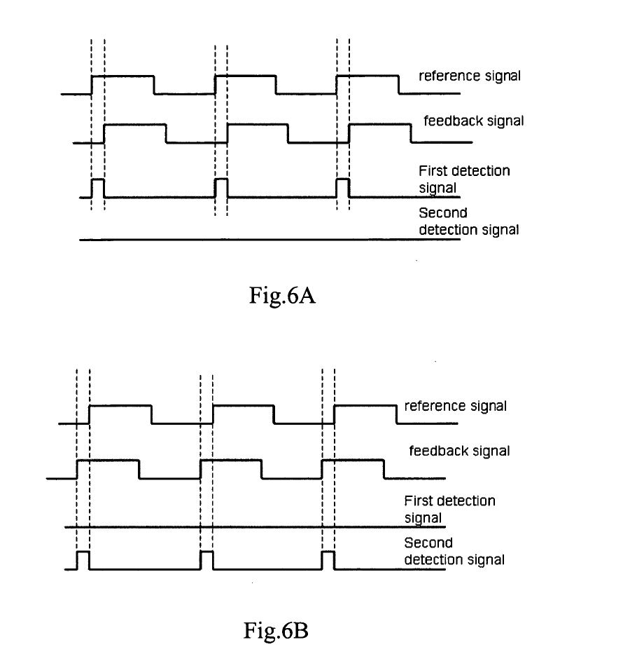

### DETAILED DESCRIPTION

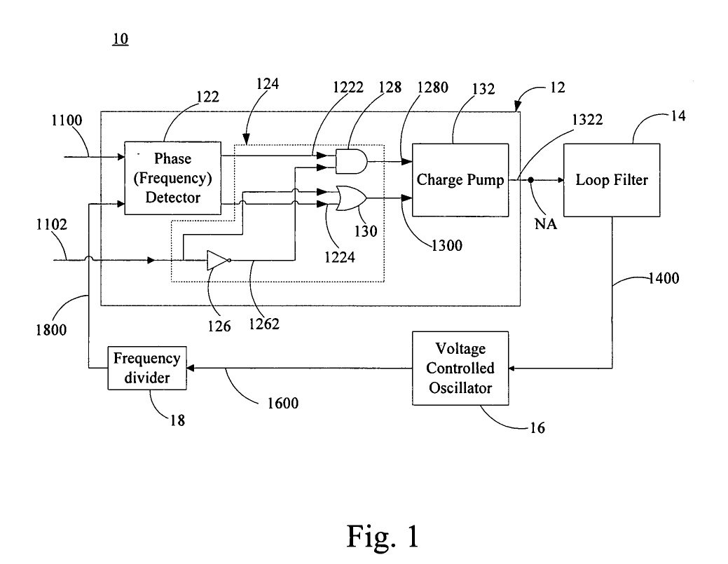

Firstly, referring to illustration of FIG. 1, a PLL apparatus 10 with power saving mode according to a first preferred embodiment of the present invention comprises a phase comparing unit 12, a loop filter 14, a voltage control oscillator (VCO) 16, and a frequency divider 18. In this embodiment, the output frequency of the VCO 16 is proportional to the control voltage 1400. Note, as it is well known in the art, the frequency divider 28 is in fact optional depending on the design consideration of the PLL apparatus. The phase comparing unit 12 receives a reference signal 1100, a feedback signal 1800, and a power saving signal 1102, and correspondingly outputs a phase difference signal 1322 at a node NA based on the reference signal 1100, the feedback signal 1800, and the power saving signal 1102.

The phase comparing unit 12 comprises a phase (frequency) detector 122, a control unit 124, and a charge pump 132. The phase (frequency) detector 122 is utilized to detect a phase difference between the reference and feedback signals 1100 and 1800, and accordingly outputs a first and second detection signals 1222 and 1224. The control unit 124 connected to the phase (frequency) detector 122 is utilized to modify the first and second detection signals 1222 and 1224, in response to the power saving signal 1102, and thereby outputs a first and second modified detection signals 1280 and 1300 to the charge pump 132. When the first modified detection signal 1280 is set at logic high, the charge pump 132 will charge the node NA; otherwise, stop charging the node NA. When the second modified detection signal 1300 is set at logic high, the charge pump 132 will discharge the node NA; otherwise, stop discharging the node NA. The control unit 124 comprises an inverter 126, an AND gate 128, and an OR gate 130. The inverter 126 receives the power saving signal 1102 and outputs an inverted power saving signal 1262. The AND gate 128 receives the inverted power saving signal 1262 and the first detection signal 1222, and thereby generating the first modified detection signal 1280 to the charge pump 132. The OR gate 130 receives the power saving signal 1102 and the second detection signal 1224, and thereby generating the second modified detection signal 1300 to the charge pump 132.

When the power saving signal 1102 is set at logic low indicating a ‘normal operation mode’, it can be seen that the first and second modified detection signals 1280 and 1300, are generated equal to the first and second detection signals 1222 and 1224, respectively. On the other hand, as soon as the power saving signal 1102 turns to be logic high indicating a ‘power saving mode’, the control unit 124 makes the first and second modified detection signals 1280 and 1300, respectively fixed at logic low and logic high, regardless of the two detection signals 1222 and 1224. Instructed by such modified detection signals 1280 and 1300, the charge pump 132 will keep discharging the node NA; in other words, discharging the loop filter 14. Therefore, the control voltage 1400 is reduced until saturated at a certain minimal level due to the physical limitation of the hardware circuit. Correspondingly, the frequency of the output signal 1600 of the VCO 16 will be kept lower than a normal working frequency to achieve power saving objective of the PLL apparatus.

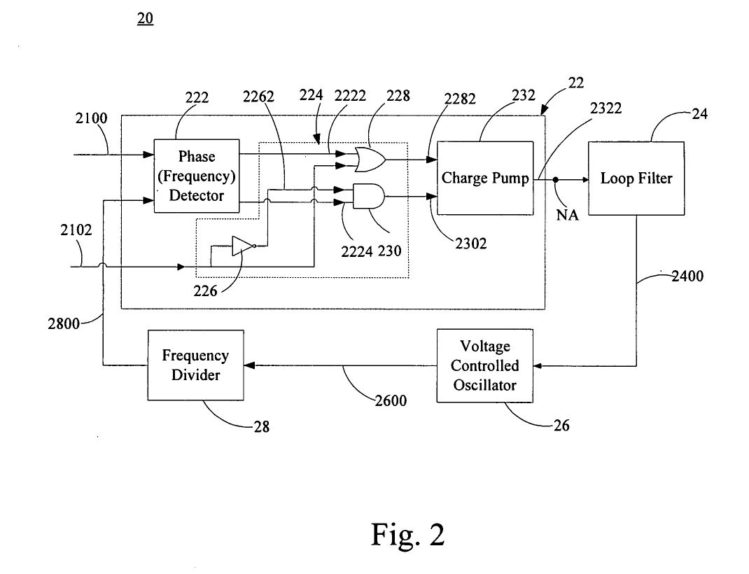

Further referring to illustration of FIG. 2, a PLL apparatus 20 with power saving mode according to a second preferred embodiment of the present invention comprises a phase comparing unit 22, a loop filter 24, a voltage control oscillator (VCO) 26, and an optional frequency divider 28. Note, as it is well known in the art, the frequency divider 28 is optional depending on the design consideration of the PLL apparatus. The second embodiment shown in FIG. 2 is similar to the first embodiment shown in FIG. 1 except for the VCO 26 and the control unit 224. In the second embodiment, an output frequency of the VCO 26 is designed inversely proportional to a control voltage 2400, and the control unit 224 comprises an inverter 226, an OR gate 228, and an AND gate 230. The inverter 226 receives a power saving signal 2102 and outputs an inverted power saving signal 2262. The OR gate 228 receives the power saving signal 2102 and a first detection signal 2222 generated from a phase detector 222, and thereby generates a first modified detection signal 2282 to the charge pump 232. The AND gate 230 receives the inverted power saving signal 2262 and a second detection signal 2224 generated from the phase detector 222, and thereby generates a second modified detection signal 2302 to the charge pump 232.

When the power saving signal 2102 is set at logic low indicating the ‘normal operation mode’, it can be found that the first and second modified detection signals 2282 and 2302 will be equal to the first and second detection signals 2222 and 2224, respectively. On the other hand, as soon as the power saving signal 2102 turns to be logic high indicating the ‘power saving mode’, the control unit 224 makes the first and second modified detection signals 2282 and 2302, respectively fixed at logic high and logic low, regardless of the first and second detection signals 2222 and 2224. Accordingly, the charge pump 232 will keep charging the node NA, i.e., charging the loop filter 24, to cause that the control voltage 2400 is successively increased until saturated at a certain maximal level due to the physical limitation of the hardware circuit. Correspondingly, the frequency of the output signal 2600 of the VCO 26 will be kept lower than a normal working frequency to achieve power saving of the PLL apparatus.

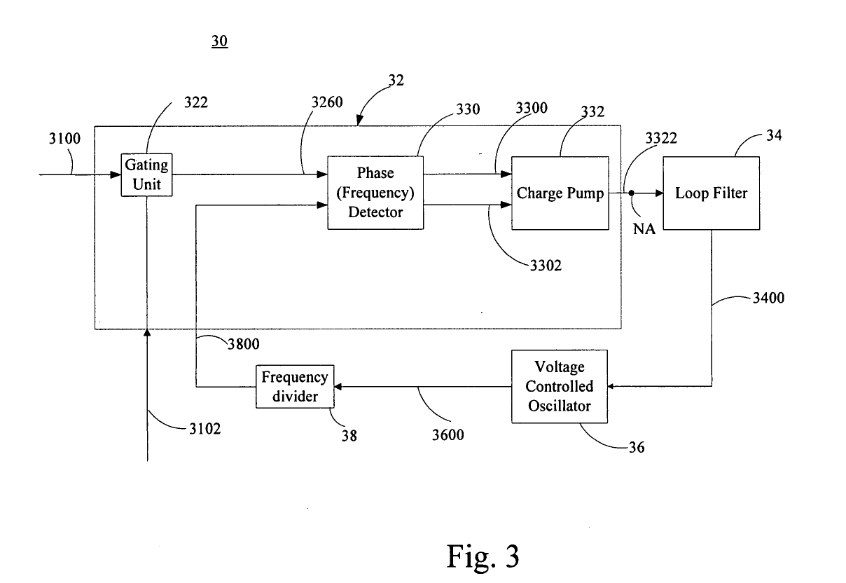

Please refer to illustration of FIG. 3, a PLL apparatus 30 with power saving mode according to a third preferred embodiment of the present invention comprises a phase comparing unit 32, a loop filter 34, and a voltage control oscillator (VCO) 36, and a frequency divider 38. In this embodiment, an output frequency of the VCO 36 is designed proportional to a control voltage 3400. Note, as it is well known in the art, the frequency divider 38 is optional depending on the design consideration of the PLL apparatus. The phase comparing unit 32 receives a reference signal 3100, a feedback signal 3800 (i.e. a divided oscillating signal generated by the frequency divider 38 in this case), and a power saving signal 3102, and correspondingly outputs a phase difference signal 3322 at a node NA, based on the reference signal 3100, the feedback signal 3800, and the power saving signal 3102.

The phase comparing unit 32 comprises a gating unit 322, a phase (frequency) detector 330 and a charge pump 332. The gating unit 322 receives the reference signal 3100 and the power saving signal 3102, and then generates a modified reference signal 3260 in response to the power saving signal 3102. The phase detector 330 receives the modified reference signal 3260 and the feedback signal 3800, and then outputs a first and second detection signals 3300 and 3302 indicating a phase difference between the modified reference signal 3260 and the feedback signal 3800. The charge pump 332 interconnecting between the phase detector 330 and the node NA, receives the first and second detection signals 3300 and 3302 to generate the phase difference signal 3322 at the node NA. When the power saving signal 3102 is set at a first level indicating a ‘power saving mode’, the gating unit 322 fixes the modified reference signal 3260 at a preset level, either at logic high or logic low, in response to the power saving signal 3102; otherwise the gating unit 322 will make the modified reference signal 3260 equal to the reference signal 3100. The gating unit 322 could simply be a logic gate, for example, if the power saving signal 3102 is set at logic high indicating the ‘power saving mode’, and the gating unit 322 can be an OR gate or an NOR gate such that the modified reference signal 3260 will be fixed at logic high or logic low. In this case, the first detection signal 3300 and the second detection signal 3302 outputted by the phase detector 330 will be kept at logic low and logic high, respectively, so as to keep the charge pump 36 discharging the node NA to decrease a control voltage 3400 which then drives a VCO 36 to output an oscillating signal 3600 at a frequency lower than a normal working frequency of the oscillating signal 3600 so as to achieve power saving objective of the PLL apparatus.

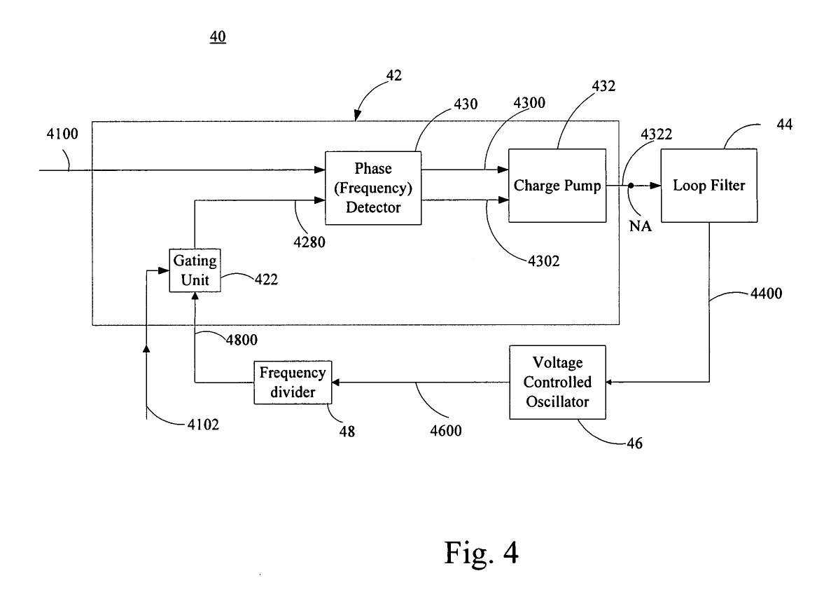

Please refer to illustration of FIG. 4, a PLL apparatus 40 with power saving mode according to a fourth preferred embodiment of the present invention comprises a phase comparing unit 42, a loop filter 44, and a voltage control oscillator (VCO) 46, and a frequency divider 48. In this embodiment, an output frequency of the VCO 46 is designed inversely proportional to a control voltage 4400. Note, as it is well known in the art, the frequency divider 48 is optional depending on the design consideration of the PLL apparatus. The phase comparing unit 42 receives a reference signal 4100, a feedback signal 4800 (i.e. a divided oscillating signal generated by the frequency divider 48 in this case), and a power saving signal 4102, and correspondingly outputs a phase difference signal 4322 at a node NA, based on the reference signal 4100, the feedback signal 4800, and the power saving signal 4102.

The phase comparing unit 42 comprises a gating unit 422, a phase (frequency) detector 430 and a charge pump 432. The gating unit 422 receives the feedback signal 4800 and the power saving signal 4102, and then generates a modified feedback signal 4280 in response to the power saving signal 4102. The phase detector 430 receives the reference signal 4100 and the modified feedback signal 4280, and then outputs a first and second detection signals 4300 and 4302 indicating a phase difference between the reference signal 4100 and the modified feedback signal 4280. The charge pump 432 receives the first and second detection signals 4300 and 4302 to generate a phase difference signal 4322 at the node NA. When the power saving signal 4102 is set at a first level indicating a ‘power saving mode’, the gating unit 422 fixes the modified feedback signal output 4280 at a preset level, either at logic high or logic low; otherwise the gating unit 422 will make the modified feedback signal 4280 equal to the feedback signal 4800 as a divided oscillating signal. The gating unit 422 could simply be a logic gate, for example, if the power saving signal 3102 is set at logic high indicating the ‘power saving mode’, and the gating unit 422 can be an OR gate or an NOR gate such that the modified feedback signal 4280 is fixed at logic high or logic low. In this case, the first detection signal 4300 and the second detection signal 4302 outputted by the phase detector 430 will be kept at logic high and logic low, respectively, so as to keep the charge pump 46 charging the node NA to increase a control voltage 4400 which then drives a VCO 46 to output a oscillating signal 4600 at a frequency lower than a normal working frequency of the oscillating signal 4600 so as to achieve power saving objective of the PLL apparatus.

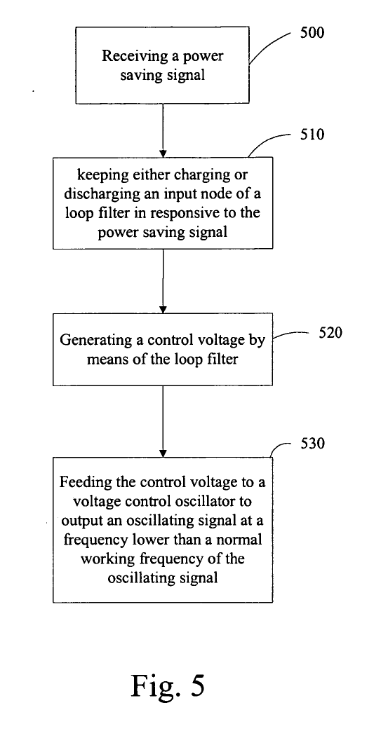

Furthermore, a flow chart of a method for implementing power saving of a PLL apparatus in accordance with the present invention is shown in FIG. 5, and comprises the following steps of:

In step 500, receiving a power saving signal, wherein while the power saving signal is at a first level (e.g., logic low) indicating a ‘normal operation mode’; otherwise while a power saving signal is at a second level (e.g., logic high) indicating a ‘power saving mode’;

In step 510, keeping either charging or discharging an input node of a loop filter when the power saving signal is set at the first level, wherein there are two ways to keep either charging or discharging an input node of a loop filter when the power saving signal is set at the first level; one way is to modify and force, by using an AND or OR gate, the output signals, i.e. the detection signals, of the phase comparing unit to be predetermined states in response to the power saving signal, such that the modified detection signals will instruct the charge pump to keep charging/discharging the loop filter; the other way is to modify and force, by using the AND or OR gate, one of the input signals of the phase comparing unit to be predetermined stat in response to the power saving signal, such that the detection signals generated by the phase comparing unit will instruct the charge pump to keep charging/discharging the loop filter;

In step 520, generating a control voltage by means of the loop filter suppressing a high frequency component of the output signal of the charge pump, wherein the control voltage will be lowered down to a lower-bound level if the charge pump keeps discharging the loop filter, and will be increased to an upper-bound level if the charge pump keeps charging the loop filter; and

In step 530, feeding the control voltage to a voltage control oscillator to output an oscillating signal at a frequency lower than a normal working frequency of the oscillating signal, so as to ultimately achieve power saving of the PLL apparatus. By utilizing the characteristics that the output frequency of the voltage control oscillator is proportional (or inversely proportional) to the control voltage, the present invention discloses many ways to make the control voltage towards either a lower-bound level or an upper-bound level such that the power consumption of the voltage control oscillator can be reduced due to its lowered output frequency.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A PLL apparatus with power saving mode, comprising:
a phase comparing unit receiving a reference signal, a feedback signal and a power saving signal, and outputting a phase difference signal at a node based on the reference signal, the feedback signal, and the power saving signal;
a loop filter coupled to the node, generating a control voltage in correspondence with the phase difference signal; and
a voltage control oscillator coupled to the loop filter, generating an oscillating signal based on the control voltage wherein if the power saving signal is set at a first level, the phase comparing unit keeps either charging or discharging the node to make the control voltage generated by the loop filter to drive the voltage control oscillator to output the oscillating signal at a frequency lower than a normal working frequency of the oscillating signal.

2. The PLL apparatus as described in claim 1 wherein the phase comparing unit comprises:
a phase detector receiving the reference and feedback signals and outputting a first and second detection signals indicating a phase difference between the reference and feedback signals;
a control unit connected to the phase detector, receiving the first and second detection signals and the power saving signal, and generating a first and second modified detection signals; and
a charge pump connected between the control unit and the node, receiving the first and second modified detection signals to generate the phase difference signal at the node.

3. The PLL apparatus as described in claim 2 wherein when the power saving signal is set at the first level, the first and second modified detection signals are set at respective preset levels by the control unit so as to keep the charge pump discharging the node to lower the control voltage thereby decreasing a frequency of the oscillating signal.

4. The PLL apparatus as described in claim 2 wherein when the power saving signal is set at the first level, the first and second modified detection signals are set at respective preset levels by the control unit so as to keep the charge pump charging the node to increase the control voltage thereby decreasing a frequency of the oscillating signal.

5. The PLL apparatus as described in claim 2 wherein the control unit comprises:
an inverter for receiving the power saving signal to output an inverted power saving signal;
a first logic gate for receiving the inverted power saving signal and the first detection signal to form the first modified detection signal; and
a second logic gate for receiving the power saving signal and the second detection signal to form the second modified detection signal.

6. The PLL apparatus as described in claim 5 wherein the first logic gate is an AND gate and the second logic gate is an OR gate.

7. The PLL apparatus as described in claim 2 wherein the control unit comprises:
an inverter for receiving the power saving signal to output an inverted power saving signal;
a first logic gate for receiving the power saving signal and the first detection signal to form the first modified detection signal; and
a second logic gate for receiving the inverted power saving signal and the second detection signal to form the second modified detection signal.

8. The PLL apparatus as described in claim 7 wherein the first logic gate is an OR gate and the second logic gate is an AND gate.

9. The PLL apparatus as described in claim 1 wherein the phase comparing unit comprises:
a gating unit receiving the reference signal and the power saving signal, and generating a modified reference signal;
a phase detector receiving the modified reference signal and the feedback signal and outputting a first and second detection signals indicating a phase difference between the modified reference signal and the feedback signal; and
a charge pump connected between the phase detector and the node, receiving the first and second detection signals to generate the phase difference signal at the node, wherein if the power saving signal is set at the first level, the gating unit fixes the modified reference signal at a preset level, otherwise the gating unit makes the modified reference signal equal to the reference signal.

10. The PLL apparatus as described in claim 9 wherein the gating unit is a logic gate.

11. The PLL apparatus as described in claim 1 wherein the phase comparing unit comprises:
a gating unit receiving the feedback signal and the power saving signal and generating a modified feedback signal;
a phase detector receiving the reference signal and the modified feedback signal and outputting a first and second detection signals indicating a phase difference between the reference signal and the modified feedback signal; and
a charge pump connected between the phase detector and the node, receiving the first and second detection signals to generate the phase difference signal at the node, wherein if the power saving signal is set at the first level, the gating unit fixes the modified feedback signal at a preset level, otherwise the gating unit makes the modified feedback signal equal to the feedback signal.

12. The PLL apparatus as described in claim 11 wherein the gating unit is a logic gate.

13. The PLL apparatus as described in claim 1 wherein the oscillating signal is fed back to the phase comparing unit to serve as the feedback signal.

14. The PLL apparatus as described in claim 1, further comprising a frequency divider coupled between the voltage control oscillator and the phase detector for dividing a frequency of the oscillating signal to generate a divided oscillating signal, which is then fed to the phase detector to serve as the feedback signal.

15. A method for implementing power saving of a PLL apparatus, comprising the steps of:
receiving a power saving signal;
keeping either charging or discharging an input node of a loop filter when the power saving signal is set at a first level;
generating a control voltage by means of the loop filter; and
feeding the control voltage to a voltage control oscillator to output an oscillating signal at a frequency lower than a normal working frequency of the oscillating signal.

16. The method as described in claim 15, wherein the step of keeping either charging or discharging the input node of the loop filter comprises:
receiving a reference signal;
generating a first and second detection signals for indicating a phase difference between the reference signal and a feedback signal;
modifying the first and second detection signals in response to the power saving signal to form a first and second modified detection signals; and
charging/discharging the input node of the loop filter by means of a charge pump in accordance with the first and second modified detection signals.

17. The method as described in claim 16, wherein when the power saving signal is set at the first level, the first and second modified detection signals are set at respective preset levels so as to keep discharging the input node of the loop filter to lower the control voltage thereby decreasing a frequency of the oscillating signal.

18. The method as described in claim 16, wherein when the power saving signal is set at the first level, the first and second modified detection signals are set at respective preset levels so as to keep charging the input node of the loop filter to increase the control voltage thereby decreasing a frequency of the oscillating signal.

19. The method as described in claim 16 wherein the step of modifying the first and second detection signals further comprises the steps of:
inverting the power saving signal to generate an inverted power saving signal;
performing a first logic operation on the first detection signal and the inverted power saving signal to form the first modified detection signal; and
performing a second logic operation on the second detection signal and the power saving signal to form the second modified detection signal.

20. The method as described in claim 19 wherein the first logic operation is an AND operation and the second logic operation is an OR operation.

21. The method as described in claim 16 wherein the step of modifying the first and second detection signals comprises the steps of:
inverting the power saving signal to generate an inverted power saving signal;
performing a first logic operation on the first detection signal and the power saving signal to form the first modified detection signal; and
performing a second logic operation on the second detection signal and the inverted power saving signal to form the second modified detection signal.

22. The method as described in claim 21 wherein the first logic operation is an OR operation and the second logic operation is an AND operation.

23. The method as described in claim 16, wherein the oscillating signal serves as the feedback signal.

24. The method as described in claim 16, wherein the feedback signal is generated by dividing a frequency of the oscillating signal.

25. The method as described in claim 15, wherein the step of keeping either charging or discharging the input node of the loop filter comprises:
receiving a reference signal;
modifying a feedback signal in response to the power saving signal to form a modified feedback signal;
generating a first and second detection signals for indicating a phase difference between the reference signal and the modified feedback signal; and
charging/discharging the input node of the loop filter by means of a charge pump in accordance with the first and second detection signals, wherein if the power saving signal is at the first level, the modified feedback signal is fixed at a preset level, otherwise the modified feedback signal equals to the feedback signal.

26. The method as described in claim 25 wherein the modified feedback signal is obtained by performing a logic operation on the power saving signal and the feedback signal.

27. The method as described in claim 25 wherein the oscillating signal serves as the feedback signal.

28. The method as described in claim 25, wherein the feedback signal is generated by dividing a frequency of the oscillating signal.

29. The method as described in claim 15, wherein the step of keeping either charging or discharging the input node of the loop filter comprises:
receiving a reference signal;
modifying the reference signal in response to the power saving signal to form a modified reference signal;
generating a first and second detection signals for indicating a phase difference between the modified reference signal and a feedback signal; and
charging/discharging the input node of the loop filter by means of a charge pump in accordance with the first and second detection signals, wherein if the power saving signal is at the first level, the modified reference signal is fixed at a preset level, otherwise the modified reference signal equals to the reference signal.

30. The method as described in claim 29 wherein the modified reference signal is obtained by performing a logic operation on the power saving signal and the reference signal.

31. The method as described in claim 29 wherein the oscillating signal serves as the feedback signal.

32. The method as described in claim 29, wherein the feedback signal is generated by dividing a frequency of the oscillating signal.
